(19) United States
(12) Patent Application Publication
(10) Pub. No.: US 2017/0005287 A1
(43) Pub. Date: Jan. 5, 2017

(54) LIGHT EMITTING DEVICE

(71) Applicants: PIONEER CORPORATION, Kawasaki-shi, Kanagawa (JP); MITSUBISHI CHEMICAL CORPORATION, Tokyo (JP)

(72) Inventors: Kaoru Suzuki, Yonezawa-shi, Yamagata (JP); Toshihiko Aoki, Yonezawa-shi, Yamagata (JP)

(21) Appl. No.: 15/038,719

(22) PCT Filed: Nov. 28, 2013
(86) PCT No.: PCT/JP2013/082108

§ 371 Date: May 23, 2016

(51) Int. Cl. H01L 51/52

(52) U.S. Cl. CPC H01L 51/5209; H01L 51/5246; H01L 51/5225; H01L 2251/5361

(57) ABSTRACT

A light emitting portion (104) of a light emitting panel (100) is configured to have a polygonal shape. A first light-emitting-side terminal (150) extends along one side of the light emitting portion (104), and a second light-emitting-side terminal (160) extends along the other side of the light emitting portion (104). The length of each of the first light-emitting-side terminal (150) and the second light-emitting-side terminal (160) is, for example, equal to or greater than 50% of the length of one side of the light emitting portion (104). The length of the connection portion (308) is equal to or greater than 10% of the length of one side of the light emitting portion (104).

### TECHNICAL FIELD

The present invention relates to a light emitting device.

### BACKGROUND ART

In recent years, development of light emitting elements including an Organic Electroluminescence (EL) element, a Light Emitting Diode (LED), or the like have continued to advance. In a case where the light emitting element is made to emit light, it is necessary to connect a feeding terminal to the light emitting element. For example, Patent Document 1 discloses disposing a support including a feeding terminal on the light emitting element and connecting the feeding terminal to the light emitting element using a copper wire, an aluminum wire, or a gold wire.

In detail, in Patent Document 1, the support is provided with an opening, and a feeding electrode provided in the light emitting element is exposed from the opening. In this manner, it is disclosed that connection between the feeding terminal and the light emitting element can be intensively performed on the back side of the support.

### RELATED DOCUMENT

### Patent Document

[Patent Document 1] Japanese Unexamined Patent Application Publication No. 2011-119239

### SUMMARY OF THE INVENTION

In a case where a light emitting element is used as a light source, it is preferable to prevent a luminance distribution from occurring in the light emitting element. A problem that the invention is to solve includes an example in which a luminance distribution is prevented from occurring in a light emitting element.

Claim 1 of the invention provides a light emitting device including a substrate, a light emitting portion that is formed on the substrate and includes a light emitting element, a terminal that is formed on the substrate and is connected to the light emitting element, an interconnect substrate, and a conductive member that connects the terminal to the interconnect substrate. The terminal extends in a direction of a width of the light emitting portion. A length of a connection portion at which the terminal and the conductive member are connected is equal to or greater than 10% of the width of the light emitting portion.

### BRIEF DESCRIPTION OF THE DRAWINGS

The above-described objects, other objects, features and advantages will become further apparent from the preferred embodiments described below, and the accompanying drawings as follows.

FIG. 1 is a plan view of a light emitting device according to an embodiment.

FIG. 2 is a side view when the light emitting device is seen from an A-direction in FIG. 1.

FIG. 3 is a plan view illustrating a configuration of a light emitting panel.

FIG. 4 is a plan view illustrating a configuration of the light emitting panel.

FIG. 5 is a plan view illustrating a configuration of the light emitting panel.

FIG. 6 is a plan view illustrating a configuration of the light emitting panel.

FIG. 7 is a cross-sectional view taken along line B-B in FIG. 3.

FIG. 8 is a cross-sectional view taken along line C-C in FIG. 3.

FIG. 9 is a cross-sectional view taken along line D-D in FIG. 3.

FIG. 10 is a cross-sectional view taken along line E-E in FIG. 3.

FIG. 11 is a cross-sectional view taken along line F-F in FIG. 3.

FIG. 12 is a plan view illustrating a first example of a modification example of the light emitting device.

FIG. 13 is a plan view illustrating the arrangement of a first interconnect-side terminal and a second interconnect-side terminal.

FIG. 14 is a diagram illustrating a second example of the modification example of the light emitting device.

FIG. 15 is a diagram illustrating a third example of the modification example of the light emitting device.

FIG. 16 is a diagram illustrating a modification example of the light emitting device.

FIG. 17 is a diagram illustrating a modification example of the light emitting device.

FIG. 18 is a diagram illustrating a modification example of the light emitting device.

### DESCRIPTION OF EMBODIMENTS

Hereinafter, embodiments of the invention will be described with reference to the accompanying drawings. In all the drawings, like reference numerals denote like components, and a description thereof will not be repeated.

### Embodiment

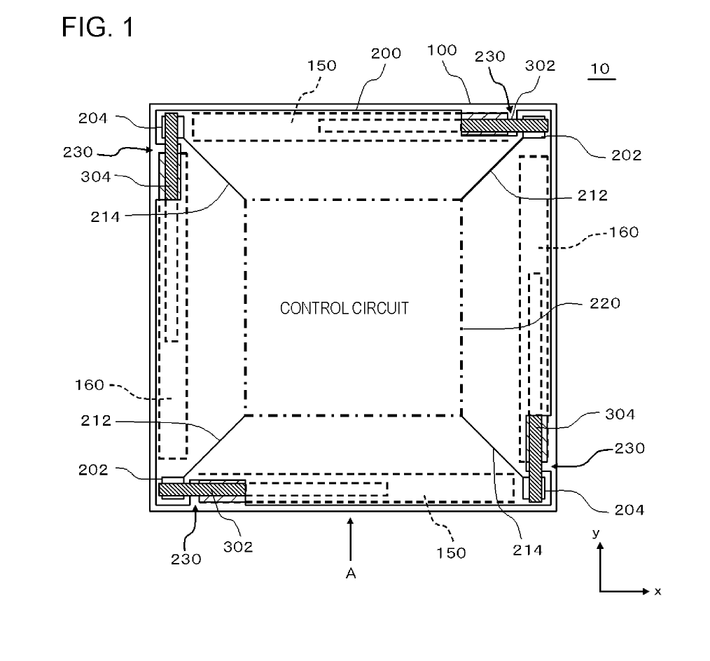

FIG. 1 is a plan view of a light emitting device 10 according to an embodiment. The light emitting device 10 includes a light emitting panel 100 and an interconnect substrate 200. FIG. 1 illustrates a state where the interconnect substrate 200 is disposed on the light emitting panel 100.

The light emitting panel 100 includes a light emitting portion 104 as described later. The light emitting portion 104 includes a plurality of light emitting elements 102 as described later. The light emitting element 102 is, for example, an organic EL element, but may be an LED element. Hereinafter, a description will be given on the assumption that the light emitting element 102 is an organic EL element. In addition, the light emitting panel 100 includes a first light-emitting-side terminal 150 and a second light-emitting-side terminal 160. The first light-emitting-side terminal 150 and the second light-emitting-side terminal 160 are connected to the light emitting element 102.

The interconnect substrate 200 is a substrate in which an interconnect is formed. The interconnect substrate 200 includes, for example, a terminal connected to the outside, a terminal connected to the light emitting panel 100, and an interconnect that connects the two terminals to each other. In addition, the interconnect substrate may include an electronic component as required. In this case, the interconnect substrate 200 serves as a circuit board.

In an example illustrated in the drawing, the interconnect substrate 200 includes at least interconnects 212 and 214, a first interconnect-side terminal 202, and a second interconnect-side terminal 204. A control circuit 220 is at least a portion of a control circuit for controlling the light emitting panel 100. The interconnect 212 connects the control circuit for controlling the light emitting panel 100 to the first interconnect-side terminal 202, and the interconnect 214 connects the control circuit to the second interconnect-side terminal 204. One (for example, the first interconnect-side terminal 202) of the first interconnect-side terminal 202 and the second interconnect-side terminal 204 is a power terminal, and the other one (for example, the second interconnect-side terminal 204) of the first interconnect-side terminal 202 and the second interconnect-side terminal 204 is a ground terminal. Meanwhile, the control circuit 220, the first interconnect-side terminal 202, and the second interconnect-side terminal 204 are formed on a surface of the interconnect substrate 200 which is opposite to the light emitting panel 100. In the example illustrated in FIG. 1, the interconnect substrate 200 is a circuit board and includes at least a portion of the control circuit 220.

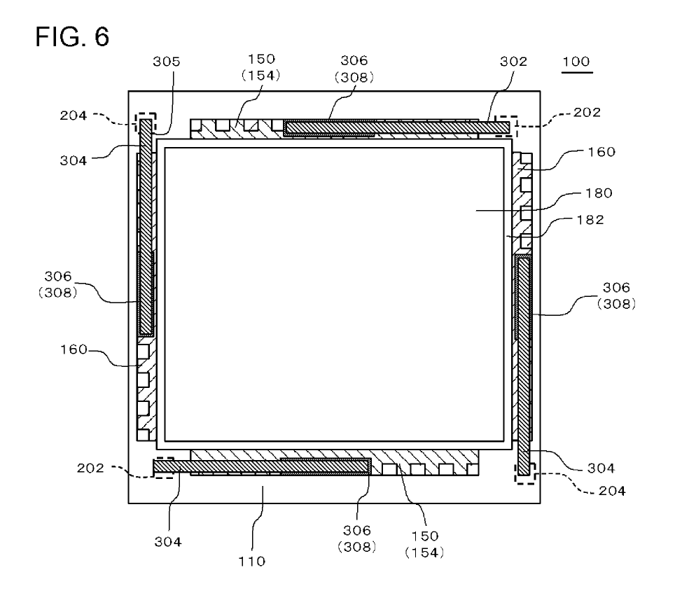

The first interconnect-side terminal 202 is connected to the first light-emitting-side terminal 150 of the light emitting panel 100 through a conductive member 302, and the second interconnect-side terminal 204 is connected to the second light-emitting-side terminal 160 of the light emitting panel 100 through a conductive member 304. The conductive member 302 and the conductive member 304 are, for example, a ribbon-like (foil-like) conductive member (for example, metallic foil such as copper foil), a plate-like conductive member, or a flexible conductive member. Each of the conductive members 302 and 304 has a planar shape which is defined, for example, by a long axis (for example, a y-direction of the conductive member 304 on the lower right side in FIG. 1) and a short axis (for example, an x-direction of the conductive member 304 on the lower right side in FIG. 1), for example, a rectangular shape. In this case, the width of the conductive member 304 in the short-axis direction is set to be equal to or greater than ten times the thickness of the conductive member 304. Thereby, resistance values of the conductive member 302 and the conductive member 304 are reduced. In addition, values of connection resistance of the first interconnect-side terminal 202 (or the second interconnect-side terminal 204) and the conductive member 302 (or the conductive member 304) are reduced. Similarly, values of connection resistance of the conductive member 302 and the first light-emitting-side terminal 150 and values of connection resistance of the conductive member 304 and the second light-emitting-side terminal 160 are also reduced. However, the conductive members 302 and 304 maybe wire-like (linear) conductive members. Meanwhile, the example illustrated in the drawing shows two or more (specifically, two) of each of the first interconnect-side terminals 202 and the first light-emitting-side terminals 150, and also two or more (specifically, two) of each of the second interconnect-side terminals 204 and the second light-emitting-side terminals 160. Meanwhile, the light emitting portion 104 mentioned above is disposed on a side of the conductive members 302 and 304 which faces an end 306 (see FIG. 6) extending in the long-axis direction. In other words, the light emitting portion 104 is disposed on a side facing a side portion in the long-axis direction in the conductive members 302 and 304.

The light emitting panel 100 and the interconnect substrate 200 have, for example, a polygonal shape. Meanwhile, the term “polygonal shape” as used herein includes a case where corners are rounded. Each side of the light emitting panel 100 is provided with the first light-emitting-side terminal 150 or the second light-emitting-side terminal 160 mentioned above. In addition, the first interconnect-side terminal 202 and the second interconnect-side terminal 204 are formed at corners different from each other in the interconnect substrate 200. More specifically, a plurality (for example, an even number) of first interconnect-side terminals 202 and a plurality (for example, an odd number) of second interconnect-side terminals 204 are formed in the interconnect substrate 200. Each of the plurality of first interconnect-side terminals 202 is disposed so as to be point-symmetrical to any of the first interconnect-side terminals 202. Similarly, each of the plurality of second interconnect-side terminals 204 is disposed so as to be point-symmetrical to any of the second interconnect-side terminals 204. For example, in the example illustrated in FIG. 1, the light emitting panel 100 and the interconnect substrate 200 have a rectangular shape such as a square shape. The first interconnect-side terminals 202 are disposed at two respective corners facing each other in the interconnect substrate 200, and the second interconnect-side terminals 204 are disposed at the remaining two respective corners. The first light-emitting-side terminal 150 (or the second light-emitting-side terminal 160) is provided between the first interconnect-side terminal 202 and the second interconnect-side terminal 204 when seen in a plan view. Meanwhile, the arrangement of the first interconnect-side terminal 202 and the second interconnect-side terminal 204 will be described later using another drawing.

At least a portion of the interconnect substrate 200 overlaps at least a portion of the light emitting panel 100. In the example illustrated in the drawing, the entire surface of the light emitting panel 100, or the entire surface except for at least a portion of an edge of the light emitting panel 100 is covered with the interconnect substrate 200. In more detail, the shape of the interconnect substrate 200 is similar (preferably identical) to the shape of the light emitting panel 100, and an area of the interconnect substrate 200 is equal to or greater than 95% and equal to or less than 105% of an area of the light emitting panel 100. For this reason, substantially the entirety of the light emitting panel 100 overlaps the entirety of the interconnect substrate 200 except for a region overlapping a cutout portion 230 to be described later. Thereby, it is possible to protect the light emitting panel 100 by the interconnect substrate 200. In addition, it is possible to reinforce the light emitting panel 100 with the interconnect substrate 200. Meanwhile, the above-mentioned area of the interconnect substrate 200 also includes an area of the cutout portion 230.

Meanwhile, in the present embodiment, the edge of the light emitting panel 100 indicates a region ranging from an end face of the light emitting panel 100 to the inside thereof to a certain degree. In other words, the edge of the light emitting panel 100 refers to an end of the light emitting panel 100. The end of the light emitting panel 100 is, for example, a region between the light emitting portion 104 (or an insulating layer 170 to be described later) of the light emitting panel 100 and the end face of the light emitting panel 100.

The cutout portion 230 is formed in an edge of the interconnect substrate 200. The cutout portion 230 is formed in the vicinity of the first interconnect-side terminal 202 and in the vicinity of the second interconnect-side terminal 204. In the example illustrated in FIG. 1, the cutout portion 230 is formed in each of four sides of the interconnect substrate 200. The plurality of cutout portions 230 are located at rotationally symmetrical positions based on an intersection point (that is, the center of the interconnect substrate 200) between diagonal lines of the interconnect substrate 200.

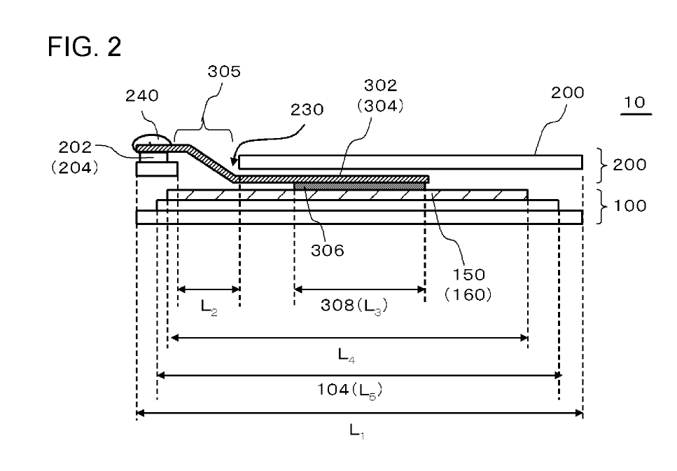

FIG. 2 is a side view when the light emitting device 10 is seen from an A-direction in FIG. 1. As illustrated in FIGS. 1 and 2, the conductive member 302 is led out from between the light emitting panel 100 and the interconnect substrate 200 to the first interconnect-side terminal 202 through the cutout portion 230. Similarly, the conductive member 304 is also led out from a region between the light emitting panel 100 and the interconnect substrate 200 to the second interconnect-side terminal 204 through the cutout portion 230. In this manner, even when at least a portion of the light emitting panel 100 is covered with at least a portion of the interconnect substrate 200, it is possible to lead out the conductive member 302 (or the conductive member 304) from between the light emitting panel 100 and the interconnect substrate 200 and to connect the conductive member to the first interconnect-side terminal 202 (or the second interconnect-side terminal 204) by the cutout portion 230 being provided.

In detail, the conductive members 302 and 304 are led out in a direction along the surface of a substrate 110 of the light emitting panel 100 from a connection portion 308 (to be described later) to thereby pass between the light emitting panel 100 and the interconnect substrate 200. Thereafter, the conductive members 302 and 304 are bent toward the interconnect substrate 200 and are led out from the cutout portion 230.

Particularly, as in the example illustrated in FIG. 1, if the conductive members 302 and 304 are to be connected to the first interconnect-side terminal 202 and the second interconnect-side terminal 204 without providing the cutout portion 230 in a case where the entire surface of the light emitting panel 100, or the entire surface except for at least a portion of the edge of the light emitting panel 100, is covered with the interconnect substrate 200, it is necessary to lead out the conductive members 302 and 304 up to the outside of the light emitting panel 100 and then to bend the conductive members 302 and 304. In this case, the light emitting device 10 becomes larger.

A width L₂ of the cutout portion 230 is, for example, equal to or less than 30% of a length L₁ of one side of the interconnect substrate 200. In this manner, it is possible to suppress a reduction in an area of a portion covered with the interconnect substrate 200 in the light emitting panel 100.

Meanwhile, the conductive member 302 extends substantially in parallel with respect to a side in which the cutout portion 230 having the conductive member 302 led out therethrough is formed. In the example illustrated in FIG. 1, the conductive member 302 extends linearly and in parallel with each of two sides of the interconnect substrate 200 which face each other when seen in a plan view, and the conductive member 304 extends linearly and in parallel with each of the remaining two sides of the interconnect substrate 200. The first light-emitting-side terminal 150 and the first interconnect-side terminal 202 are located on an extended line of the conductive member 302 when seen in a plan view, and the second light-emitting-side terminal 160 and the second interconnect-side terminal 204 are located on an extended line of the conductive member 304. In other words, the conductive member 302 linearly connects the first light-emitting-side terminal 150 to the first interconnect-side terminal 202, and the conductive member 304 linearly connects the second light-emitting-side terminal 160 to the second interconnect-side terminal 204. When seen in a direction which is perpendicular to the side in which the cutout portion 230 is formed (for example, a vertical direction in FIG. 1 for the first interconnect-side terminal 202, and a horizontal direction in FIG. 1 for the second interconnect-side terminal 204), at least a portion of the first interconnect-side terminal 202 (or the second interconnect-side terminal 204) which is located next to the cutout portion 230 overlaps the cutout portion 230. Thereby, even when the conductive member 302 (or the conductive member 304) is not bent in a planar direction after being led out from the cutout portion 230, the conductive member can be connected to the first interconnect-side terminal 202 (or the second interconnect-side terminal 204). Thereby, the reliability of the conductive members 302 and 304 is improved. In addition, since the conductive member 302 is connected to the first interconnect-side terminal 202 and the conductive adhesive 306 through surface connection, deformation in the planar direction is not likely to occur. Similarly, regarding the conductive member 304, deformation in the planar direction is not likely to occur. Therefore, the reliability of the conductive members 302 and 304 is further improved.

In addition, in a case where a sealing member 180 to be described later is formed of a conductive material such as aluminum or iron and a conductive member which is deformable in the planar direction of the substrate 100 to be described later is disposed parallel to the sealing member 180, the conductive members 302 and 304 and the sealing member 180 may electrically come into contact with and short-circuit each other. However, in the present embodiment, the conductive members 302 and 304 are not likely to be deformed in the planar direction of the substrate 100. For this reason, even when the conductive members 302 and 304 are disposed so as to be aligned with a predetermined interval from the sealing member 180, it is possible to draw the conductive members 302 and 304 while suppressing the occurrence of short-circuiting between the sealing member 180 and the conductive members 302 and 304. Therefore, the reliability of the light emitting device 10 is improved.

In addition, the first interconnect-side terminal 202 and the second interconnect-side terminal 204 are located at positions (upper side in FIG. 2) which are different from the light emitting panel 100 in the thickness direction of the light emitting panel 100. On the other hand, the conductive members 302 and 304 have a ribbon shape, a plate shape, or a foil shape having flexibility in the thickness direction of the substrate 110, and the width direction thereof is parallel to the surface direction of the light emitting panel 100. Therefore, the conductive members 302 and 304 are easily deformed in the thickness direction of the light emitting panel 100, and thus can be easily connected to the first interconnect-side terminal 202 and the second interconnect-side terminal 204, respectively.

Meanwhile, as illustrated in the drawing, the conductive members 302 and 304 have a bent portion 305 which is bent in the thickness direction of the light emitting panel 100. The bent portion 305 is located inside the cutout portion 230. In detail, a predetermined interval is provided between the interconnect substrate 200, and the conductive members 302 and 304. In a state of being separated from the cutout portion 230, the bent portion 305 of each of the conductive members 302 and 304 is bent to the light emitting panel 100 side, bent to the interconnect substrate 200, and then connected to the first interconnect-side terminal 202 or the second interconnect-side terminal 204. For this reason, it is possible to prevent the conductive members 302 and 304 from coming into contact with the cutout portion 230 and being disconnected.

In addition, as illustrated in FIG. 2, the first light-emitting-side terminal 150 is connected to the conductive member 302 through the conductive adhesive 306. Similarly, the second light-emitting-side terminal 160 is also connected to the conductive member 302 through the conductive adhesive 306. The conductive adhesive layer 306 is, for example, a mixture of an adhesive resin and conductive particles such as metal particles. As illustrated in FIGS. 1 and 2, a portion (the connection portion 308) of the conductive member 302 (or the conductive member 304) which is connected to the first light-emitting-side terminal 150 (or the second light-emitting-side terminal 160) is covered with the interconnect substrate 200. For this reason, it is possible to suppress deviation of the conductive member 302 (or the conductive member 304) from the first light-emitting-side terminal 150 (or the second light-emitting-side terminal 160) due to an external force being applied to the connection portion 308. Specifically, even when an external force in the thickness direction of the substrate 110 is applied to the light emitting device 10, it is possible to suppress peeling of the conductive member 302 (or the conductive member 304) from the first light-emitting-side terminal 150 (or the second light-emitting-side terminal 160). Meanwhile, the connection portion 308 is formed at a position (different position) which does not overlap the cutout portion 230.

In addition, as described later in detail, the substrate 110 of the light emitting panel 100 has a polygonal shape (for example, a rectangular shape). The light emitting portion 104 (to be described later in detail) of the light emitting panel 100 is also configured to have a polygonal shape similar to that of the light emitting panel 100. The first light-emitting-side terminal 150 extends in a direction of a certain width of the light emitting portion 104, and the second light-emitting-side terminal 160 extends in a width direction in the light emitting portion 104 different from the first light-emitting-side terminal 150. In other words, the first light-emitting-side terminal 150 extends along one side of the substrate 110 and one side of the light emitting portion 104, and the second light-emitting-side terminal 160 extends along the other side of the substrate 110 and the other side of the light emitting portion 104. A length L₄ of the first light-emitting-side terminal 150 (or the second light-emitting-side terminal 160) is, for example, equal to or greater than 50% of a length L₅ of one side of the light emitting portion 104. A length L₃ of the connection portion 308 is equal to or greater than 10% of the length L₅ of one side of the light emitting portion 104. For this reason, it is possible to reduce the value of contact resistance between the first light-emitting-side terminal 150 (or the second light-emitting-side terminal 160) and the conductive member 302 (or the conductive member 304) by increasing a contact area therebetween. In addition, since the generation of a current distribution or a voltage distribution in an electrode of the light emitting panel 100 can be suppressed, it is possible to suppress the generation of a luminance distribution inside the light emitting panel 100.

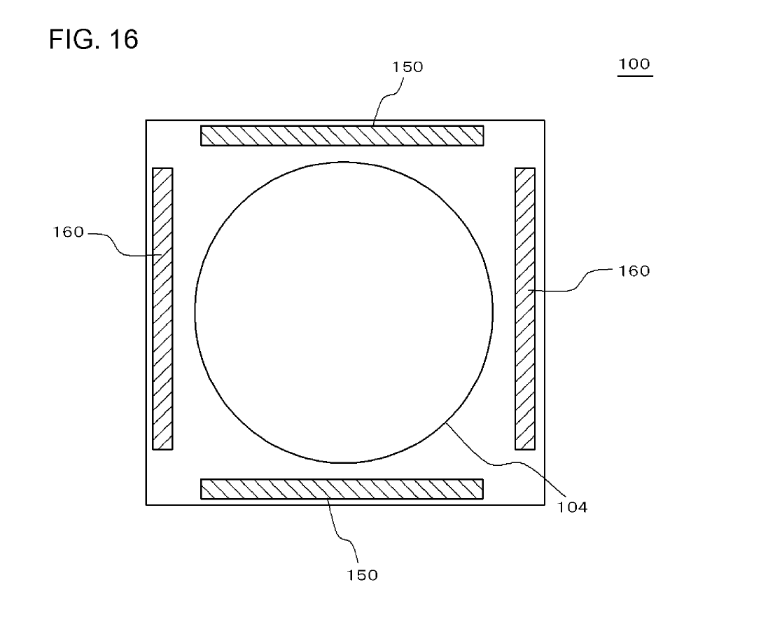

Meanwhile, as illustrated in FIG. 16, the light emitting portion 104 may have a circular shape or an elliptical shape. In a case where the light emitting portion 104 has a circular shape, the width of the light emitting portion 104 is set to be the diameter of the light emitting portion 104. In addition, in a case where the light emitting portion 104 has an elliptical shape, one width of the light emitting portion 104 is set to be a major axis, and the other width of the light emitting portion 104 is set to be a minor axis.

It is preferable that the length L₃ of the connection portion 308 is equal to or greater than 40% of the length L₅ of one side of the light emitting portion 104. In this manner, it is possible to further reduce the value of contact resistance between the first light-emitting-side terminal 150 (or the second light-emitting-side terminal 160) and the conductive member 302 (or the conductive member 304).

On the other hand, when the length L₃ of the connection portion 308 is set to be excessively large, it is necessary to increase the lengths of the conductive members 302 and 304, and thus the cost of the light emitting device 10 increases. For this reason, it is preferable that the length of the connection portion 308 is equal to or less than 80% of the length L₅ of one side of the light emitting portion 104. In addition, the length L₃ of the connection portion 308 can also be defined based on the width of the substrate 110. In this case, the length L₃ of the connection portion 308 is preferably equal to or greater than 10% of the width of the substrate 110 in a direction parallel to the connection portion 308, and is further preferably equal to or less than 80%. The reason for the preference is as described above.

Meanwhile, it is preferable that the connection portion 308 overlaps the center of the light emitting portion 104 in the width direction of the light emitting portion 104, and it is particularly preferable that both ends of the connection portion 308 are located at positions that are symmetrical to each other based on the center of the light emitting portion 104. In this manner, since the generation of a current distribution or a voltage distribution in the electrode of the light emitting panel 100 can be further suppressed, it is possible to further suppress the generation of a luminance distribution inside the light emitting panel 100.

Further, a portion of the conductive member 302 which comes into contact with at least the first interconnect-side terminal 202 is not covered with an insulating member. That is, the entire circumference of the portion is configured as an electrically connectable connection surface inclusive of a surface on the substrate 110 side and a surface on the opposite side, and a conductive material is exposed at the entire circumference. For this reason, a connection area between the first interconnect-side terminal 202 and the conductive member 302 is increased, and thus it is possible to reduce the value of connection resistance therebetween. Particularly, in the present embodiment, the conductive member 302 has a foil shape, and a ratio of the width to the thickness thereof is set to be equal to or greater than ten to one. For this reason, not only the lower surface of the conductive member 302 but also the upper surface thereof is also electrically connected to the first interconnect-side terminal 202, and thus the value of connection resistance between the first interconnect-side terminal 202 and the conductive member 302 is particularly reduced.

In addition, since a surface of the conductive member 302 on the substrate 110 side and a surface on the opposite side thereof are configured as electrically connectable connection surfaces, in a case where the surface of the conductive member 302 on the substrate 110 side is configured as a connection surface with respect to the first interconnect-side terminal 202 or the second interconnect-side terminal 204 as in the present embodiment, a surface of the conductive member 302 on the side opposite to the substrate 110 is also configured as an electrically connectable surface, and thus it is possible to confirm the presence or absence of electrical conduction using the surface. Specifically, it is possible to check whether or not the first interconnect-side terminal 202 and the conductive member 302 are connected to each other using a tester or the like, and to check whether or not the second interconnect-side terminal 204 and the conductive member 304 are connected to each other using a tester or the like.

Similarly, when the surface on the substrate 110 side in the conductive member 304 on the substrate 119 side is configured as a contact surface to the first light-emitting-side terminal 150 or the second light-emitting-side terminal 160, it is possible to confirm the presence or absence of electrical conduction using surfaces of the conductive members 302 and 304 on the side opposite to the substrate 110. Specifically, it is possible to check whether or not the conductive member 302 and the first light-emitting-side terminal 150 are connected to each other using a tester or the like, and to check whether or not the conductive member 304 and the second light-emitting-side terminal 160 using a tester or the like.

In addition, a force in a direction moving away from the first interconnect-side terminal 202 may be applied to a portion of the conductive member 302 which is connected to the first interconnect-side terminal 202, due to the elastic force of the conductive member 302. On the other hand, in the example illustrated in the drawing, the conductive member 302 and the first interconnect-side terminal 202 are connected to each other through solder 240 (another conductive member). Thereby, it is possible to suppress the disconnection of a connection portion between the conductive member 302 and the first interconnect-side terminal 202 due to the above-mentioned force. In addition, the area of a portion of the conductive member 302 which is electrically connected to the first interconnect-side terminal 202 is further increased. In addition, it is possible to reliably connect the conductive member 302 and the first interconnect-side terminal 202. In addition, it is also possible to easily connect a surface of the conductive member 302 on a side opposite to the first interconnect-side terminal 202 to the first interconnect-side terminal 202.

Meanwhile, a connection portion of the conductive member 304 and the second interconnect-side terminal 204 is configured in the same manner as the connection portion of the conductive member 302 and the first interconnect-side terminal 202, and thus the same effects are obtained.

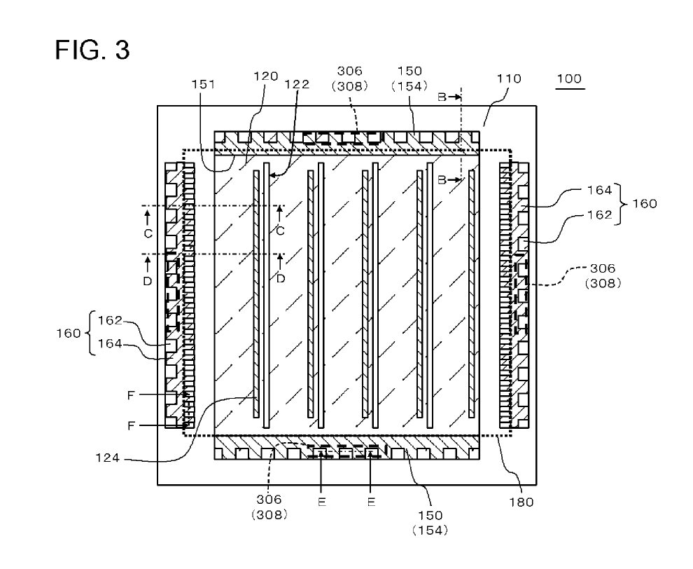

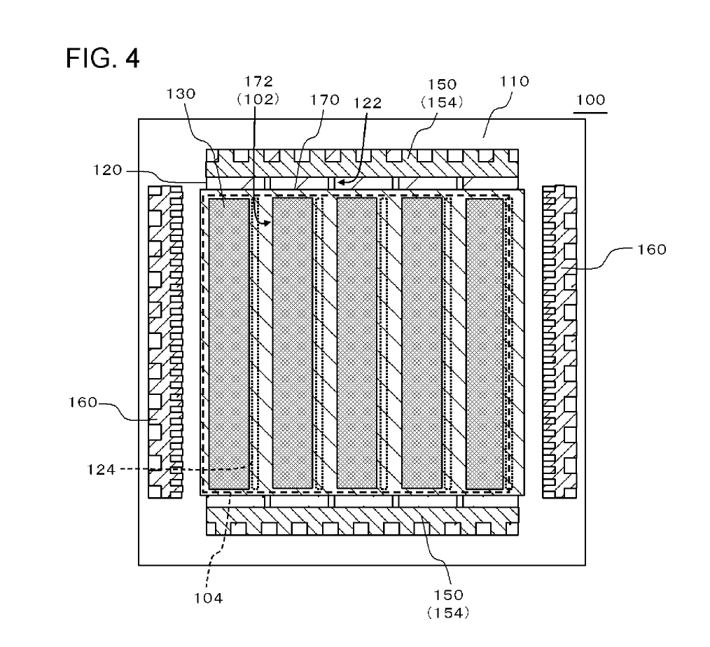

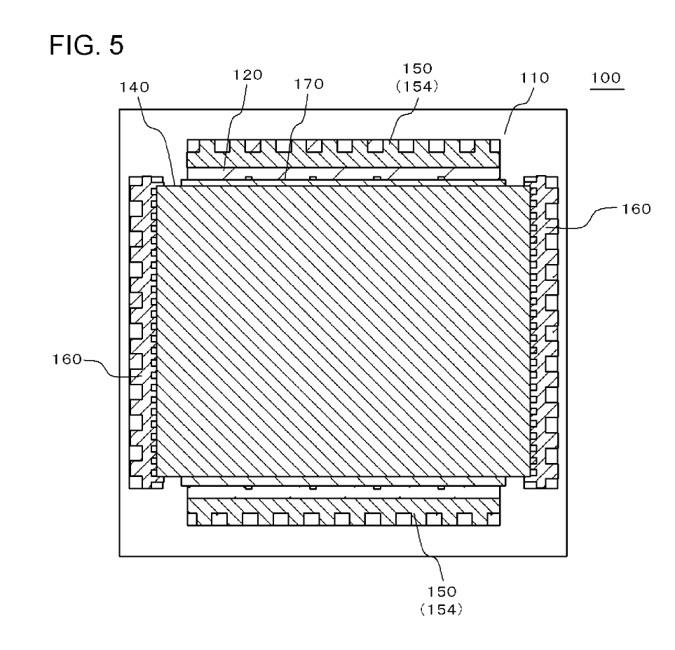

FIGS. 3 to 6 are plan views illustrating a configuration of the light emitting panel 100. FIG. 5 is a diagram in which the sealing member 180, the conductive members 302 and 304, and the conductive adhesive 306 are removed from FIG. 6, FIG. 4 is a diagram in which a second electrode 140 is removed from FIG. 5, and FIG. 3 is a diagram in which an organic layer 130 and the insulating layer 170 are removed from FIG. 4. In FIG. 3, the sealing member 180 is shown by a dotted line for description.

In the example illustrated in the drawing, the light emitting panel 100 includes the plurality of light emitting elements 102 as illustrated in FIG. 4. The light emitting portion 104 is formed by the plurality of light emitting elements 102. In the example illustrated in the drawing, the light emitting portion 104 is located between two first light-emitting-side terminals 150 which are separated from each other, and are located between two second light-emitting-side terminals 160 which are separated from each other. In this manner, a current or a voltage is supplied to the first electrode 120 from the plurality of first light-emitting-side terminals 150 and a current or a voltage is supplied to the second electrode 140 from the plurality of second light-emitting-side terminals 160, and thus it is possible to suppress the generation of a distribution in a current or a voltage inside the light emitting portion 104. Thereby, it is possible to suppress the generation of a luminance distribution in the light emitting portion 104.

In addition, the plurality of light emitting elements 102 are aligned in a direction (horizontal direction in FIG. 4) in which the first light-emitting-side terminal 150 on the first light emitting side extends. In the example illustrated in the drawing, the light emitting element 102 has a rectangular shape and has a short side directed in a direction which is parallel to the first light-emitting-side terminal 150.

The light emitting element 102 is configured such that the first electrode 120 (first conductive film), the organic layer 130, and the second electrode 140 are laminated on the substrate 110. In the example illustrated in the drawing, the first electrode 120, the organic layer 130, and the second electrode 140 are laminated on the substrate 110 in this order. However, the first electrode 120 and the second electrode 140 may be reversed.

The substrate 110 is a transparent substrate such as a glass substrate or a resin substrate. The substrate 110 may have flexibility. Also in this case, the thickness of the substrate 110 is, for example, equal to or greater than 10 pm and equal to or less than 1000 μm. In this case, the substrate 110 may be formed of either an inorganic material or an organic material. The substrate 110 has a polygonal shape such as a rectangular shape.

In the present embodiment, the first electrode 120 functions as an anode, and the second electrode 140 functions as a cathode. One (in the example illustrated in the drawing, the first electrode 120) of the first electrode 110 and the second electrode 140 is a transparent electrode having light transmitting properties. Examples of a material of the transparent electrode include an inorganic material, such as Indium Tin Oxide (ITO) or Indium Zinc Oxide (IZO), and a conductive polymer such as a polythiophene derivative.

In addition, the other one (in the example illustrated in the drawing, the second electrode 140) of the first electrode 120 and the second electrode 140 includes a metal selected from a first group constituted by Au, Ag, Pt, Sn, Zn, and In, or a metal layer formed of an alloy of metals selected from the first group.

More specifically, as illustrated in FIG. 3, the first electrode 120 is connected to the first light-emitting-side terminal 150. The first electrode 120 is formed continuously from a region of the substrate 110 which serves as the light emitting portion 104, to the first light-emitting-side terminal 150. In the example illustrated in the drawing, the substrate 110 has a rectangular shape, and the first light-emitting-side terminals 150 are provided along two sides facing each other. The first electrode 120 is formed between the two sides.

The first electrode 120 is provided with a plurality of openings 122. The openings 122 extend between the plurality of light emitting elements 102, and divide the first electrode 120 into the plurality of individual light emitting elements 102. The first electrode 120 included in any of the light emitting elements 102 is also connected to the first light-emitting-side terminal 150. For this reason, even when the openings 122 are formed, the first electrode 120 functions as an electrode common to the plurality of light emitting elements 102. Meanwhile, a portion of the electrode 120 which is located in the vicinity of the first light-emitting-side terminal 150 may not include the opening 122.

An auxiliary electrode 124 is provided on the first electrode 120. The auxiliary electrode 124 is provided in each of the plurality of light emitting elements 102, and is located in the vicinity of the opening 122. The auxiliary electrode 124 is formed of a material (for example, a metal such as Al) which has a resistance value lower than that of the first electrode 120. It is possible to suppress the occurrence of a voltage drop in the plane of the first electrode 120 by the auxiliary electrode 124 being formed. Thereby, it is possible to suppress the generation of a luminance distribution in the light emitting panel 100.

Meanwhile, in the example illustrated in the drawing, the auxiliary electrode 124 extends between two first light-emitting-side terminals 150, but is not directly connected to either of the two first light-emitting-side terminals 150.

A second layer 154 of the first light-emitting-side terminal 150 is formed on a region of the first electrode 120 which is to serve as the first light-emitting-side terminal 150. In other words, the first light-emitting-side terminal 150 on the first light emitting side is configured such that the same layer (a first layer 152) as the first electrode 120 and the second layer 154 are laminated. The first layer 152 is integrated with the first electrode 120. For this reason, it is possible to reduce the resistance value between the first light-emitting-side terminal 150 and the first electrode 120 by reducing the distance therebetween. In addition, it is possible to narrow a non-light emission region which is present at an edge of the light emitting panel 100.

The second layer 154 is formed of a material (a metal such as Al, or a laminated film of metals of Mo, Al, Mo, and the like) which has a resistance value lower than that of the first electrode 120. The conductive adhesive 306 (connection portion 308) is connected to the second layer 154. Meanwhile, the second layer 154 has light transmittance lower than (that is, has light shielding properties higher than) that of the first electrode 120.

A plurality of openings are formed in the second layer 154 of the first light-emitting-side terminal 150. In the example illustrated in the drawing, the plurality of openings are aligned in the direction in which the terminal 150 on the first light emitting side extends. In detail, the plurality of openings are connected to a side of the second layer 154 which faces an edge (side surface) of the substrate 110. For this reason, the second layer 154 is formed to have a comb tooth shape. At least a portion of the conductive adhesive 306 overlaps the openings. In other words, a portion of the first layer 152 of the first light-emitting-side terminal 150 is not covered with the second layer 154. The portion which is not covered with the second layer overlaps the conductive adhesive 306.

Meanwhile, a side portion 151 (see FIG. 3) of the first light-emitting-side terminal 150 which faces the light emitting portion 104 is along the side portion of the conductive member 302 in the long-axis direction. Thereby, it is possible to make a current uniformly flow to the light emitting portion 104 from the connection portion 308. As illustrated in the drawing, in a case where the second layer 154 is formed from one end of the light emitting portion 104 to the other end in the long-axis direction (horizontal direction in FIG. 3) of the conductive member 302 (that is, is larger than the width of the light emitting portion 104 in this direction), this effect is particularly heightened.

In addition, the second light-emitting-side terminal 160 is configured such that a second layer 164 is laminated on a first layer 162. The first layer 162 is formed of the same material as that of the first electrode 120. However, the first layer 162 is separated from the first electrode 120. The second layer 164 is formed of the same material as that of the second layer 154. In addition, a plurality of openings are formed in the first layer 162, similar to the second layer 154. Aside of the first layer 162 which faces the edge of the substrate 110 is formed to have a comb tooth shape. At least a portion of the conductive adhesive 306 overlaps the openings, that is, a portion of the first layer 162 which is not covered with the second layer 164. Meanwhile, the second light-emitting-side terminal 160 does not need to include the first layer 162.

Further, a plurality of second openings are formed in a side of the second layer 164 which faces the first electrode 120. The width of the plurality of second openings in a direction in which the second light-emitting-side terminal 160 extends is narrower than the width of the openings overlapping the conductive adhesive 306. In the example illustrated in the drawing, the plurality of second openings are connected to the side of the second layer 164 which faces the first electrode 120. For this reason, the second layer 164 is configured such that the side thereof facing the first electrode 120 is also formed to have a comb tooth shape. The edge of the sealing member 180 overlaps the comb tooth portions (second openings).

In addition, as illustrated in FIG. 4, the insulating layer 170 is formed on a region of the first electrode 120 which is not covered with the second layer 154. The insulating layer 170 is formed of a photosensitive resin such as polyimide. The insulating layer 170 is provided with a plurality of openings 172. The openings 172 extend so as to be parallel to the openings 122 and the auxiliary electrodes 124. However, the openings 172 do not overlap the auxiliary electrodes 124 and the openings 122 of the first electrodes 120. For this reason, the auxiliary electrodes 124 are covered with the insulating layer 170, and a portion of the openings 122 which is located inside the light emitting portion 104 is also covered with the insulating layer 170.

The organic layer 130 mentioned above is formed at least on the inside of the opening 172. The organic layer 130 includes a light emitting layer. A voltage is applied between the first electrode 120 and the second electrode 140 inside the opening 172, and thus the organic layer 130 emits light. In other words, the light emitting element 102 is formed inside each of the openings 172.

Light emitted from the light emitting element 102 is emitted to the outside through an electrode (first electrode 120 in the example illustrated in the drawing) which is configured as a transparent electrode out of the first electrode 120 and the second electrode 140. The organic layer 130 is configured such that, for example, a hole injection layer, a light emitting layer, and an electron injection layer are laminated in this order. A hole transport layer may be formed between the hole injection layer and the light emitting layer. In addition, an electron transport layer may be formed between the light emitting layer and the electron injection layer. At least one layer in the organic layer 130 is formed by a coating method. Meanwhile, the remaining layers in the organic layer 130 are formed by a vapor deposition method. Additionally, the organic layer 130 may be formed of a coating material by an ink jet method, a printing method, or a spraying method.

In addition, as illustrated in FIG. 5, the second electrode 140 is formed of an electrode which is common to the plurality of light emitting elements 102. In detail, the second electrode 140 is formed on the organic layer 130 and the insulating layer 170, and is connected to the second light-emitting-side terminal 160. In the example illustrated in the drawing, the second light-emitting-side terminal 160 is formed along two sides of the substrate 110 which face each other. The second electrode 140 is formed so as to cover a region between the two second light-emitting-side terminals 160.

In addition, as illustrated in FIG. 6, the plurality of light emitting elements 102 are sealed by the sealing member 180. The sealing member 180 has a shape in which the entire circumference of an edge portion 182 of metallic foil or a metal plate (for example, Al foil or an Al plate) having the same polygonal shape as the substrate 110 is pressed down. The edge portion 182 is fixed to the substrate 110. As described later in detail, a portion of the edge portion 182 overlaps the second openings of the second light-emitting-side terminal 160.

Meanwhile, when seen in a plan view, the edge portion 182 of the sealing member 180 is located further on the inside of the light emitting panel 100 than the conductive adhesive 306 and the connection portion 308. For this reason, the connection portion 308 does not overlap the sealing member 180, and thus the conductive member 302 (or the conductive member 304) can be connected to the first light-emitting-side terminal 150 (or the second light-emitting-side terminal 160).

In addition, in the present embodiment, the first interconnect-side terminal 202 and the second interconnect-side terminal 204 are disposed at respective corners of the interconnect substrate 200. In addition, the first light-emitting-side terminal 150 is disposed on the inner side of one side of the substrate 100, and is disposed between the first interconnect-side terminal 202 and the second interconnect-side terminal 204 when seen in a plan view. Similarly, the second light-emitting-side terminal 160 is also disposed on the inner side of one side of the substrate 100 which is different from the first light-emitting-side terminal 150, and is disposed between the first interconnect-side terminal 202 and the second interconnect-side terminal 204 when seen in a plan view. One ends of the conductive members 302 and 304 are respectively connected to the light-emitting-side terminals 150 and 160, and the other ends thereof are respectively connected to the first interconnect-side terminal 202 and the second interconnect-side terminal 204. At this time, a direction from the one ends of the conductive members 302 and 304 toward the other ends is along a circumferential direction of the substrate 100. In other words, the direction from the one ends of the conductive members 302 and 304 toward the other ends is set to be a direction of going once around an outer peripheral portion of the substrate 100. For this reason, when the conductive members 302 and 304 are led out from the cutout portion 230 of the interconnect substrate 200, it is possible to perform the lead-out operation while rotating the substrate 100. Therefore, it is possible to easily lead out the conductive members 302 and 304.

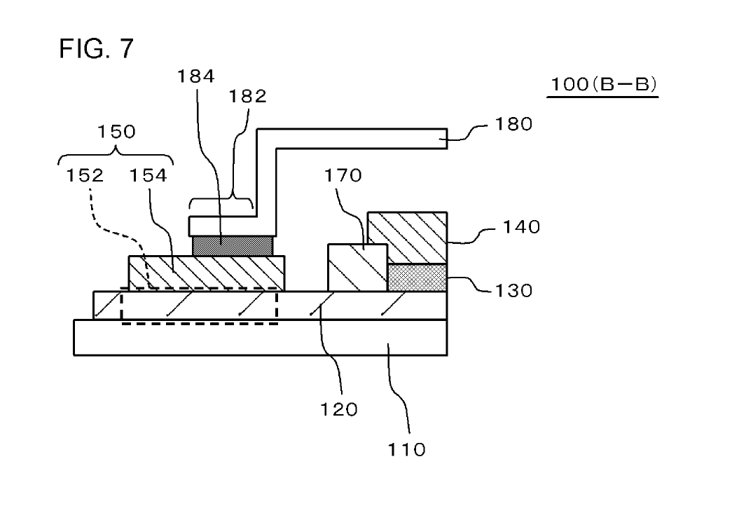

FIG. 7 is a cross-sectional view taken along line B-B in FIG. 3. As described above, the first light-emitting-side terminal 150 is configured such that the second layer 154 is laminated on an end (the first layer 152) of the first electrode 120. In addition, the organic layer 130 is sealed by the sealing member 180. A desiccant may be disposed inside the sealing member 180. The edge portion 182 of the sealing member 180 is fixed to a layer (the second layer 154 in a B-B cross-section) which is formed on the substrate 110 through an insulating adhesive layer 184. However, a portion of the second layer 154 which is close to the edge of the substrate 110 is exposed from the edge portion 182. The conductive member 302 is connected through the conductive adhesive 306 to a portion of the second layer 154 which is not exposed from the edge portion 182.

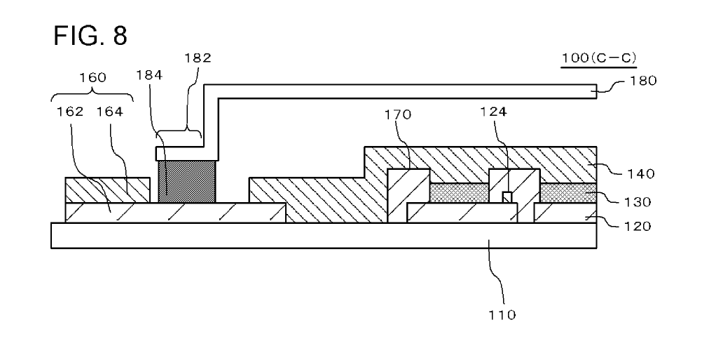

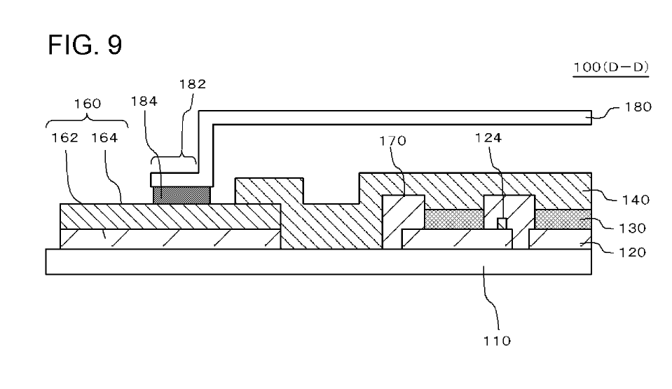

FIG. 8 is a cross-sectional view taken along line C-C in FIG. 3, and FIG. 9 is a cross-sectional view taken along line D-D in FIG. 3. As described above, the second light-emitting-side terminal 160 is configured such that the second layer 164 (light shielding layer) is laminated on the first layer 162. The second layer 164 has at least one opening. In detail, a region of the second layer 164 on the organic layer 130 side has a comb tooth shape and includes a portion (C-C cross-section) which is not covered with the second layer 164 and a portion (D-D cross-section) which is covered with the second layer 164. In the C-C cross-section and the D-D cross-section, the edge portion 182 of the sealing member 180 is fixed to the second light-emitting-side terminal 160 through the insulating adhesive layer 184. In more detail, as shown in the C-C cross-section, a portion of the adhesive layer 184 is fixed to the first layer 162 in a region (opening of the second layer 164) which is located between the teeth of the comb teeth of the second layer 164. In addition, as shown in the D-D cross-section, another portion of the adhesive layer 184 is fixed to the second layer 164.

In a case where the edge portion 182 of the sealing member 180 is fixed to the substrate 110 using the adhesive layer 184, there is the possibility of air bubbles entering between the adhesive layer 184 and the substrate 110. When the air bubbles are generated, the sealing ability of the sealing member 180 is deteriorated. In the present embodiment, at least a portion of the edge portion 182 overlaps the second light-emitting-side terminal 160. The second layer 164 has an opening, and the first layer 162 is formed of a light transmissive material. For this reason, in a case where air bubbles are mixed into an interface between the adhesive layer 184 and the second light-emitting-side terminal 160, it is possible to check the air bubbles from a surface (that is, on a light emitting surface side) of the substrate 110 which is not sealed with the sealing member 180. Particularly, in the present embodiment, since a portion of the second layer 164 which overlaps the edge portion 182 is formed to have a comb tooth shape, the presence or absence of air bubbles is easily confirmed.

In addition, in the present embodiment, since the presence or absence of air bubbles can be confirmed using the second layer 164 of the second light-emitting-side terminal 160, it is not necessary to provide a light shielding pattern for checking the presence or absence of air bubbles. Therefore, it is possible to suppress an increase in an area of a non-light emission region of the light emitting panel 100. This effect is particularly heightened in a case where the second light-emitting-side terminal 160 is formed along the edge of the substrate 110 as in the present embodiment. In addition, in a case where the second light-emitting-side terminal 160 is connected to the second electrode 140 as a cathode formed of a conductive material such as Al which has a relatively small resistance value, a voltage distribution or a current distribution is hardly generated within a film constituting the second electrode 140. For this reason, it is possible to provide an opening in the second layer 164 of the second light-emitting-side terminal 160. In this regard, it is possible to check the presence or absence of air bubbles in an interface between the adhesive layer 184 and the second light-emitting-side terminal 160 by opening a portion of the second layer 164 for forming the light shielding pattern.

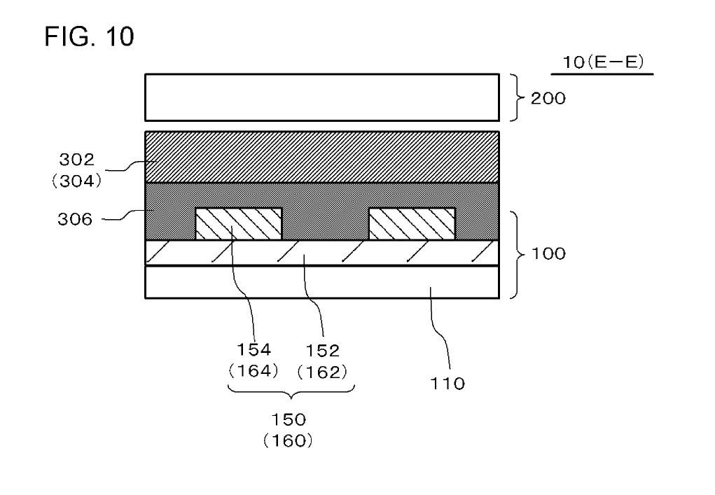

FIG. 10 is a cross-sectional view taken along line E-E in FIG. 3. As described above using FIG. 3, a plurality of openings are formed in the second layer 154 of the first light-emitting-side terminal 150. At least a portion of the conductive adhesive 306 overlaps the openings. For this reason, a portion of the conductive adhesive 306 enters the opening of the second layer 154 and is connected to the first layer 152. The first layer 152 and the substrate 110 have light transmitting properties. Therefore, in a case where the light emitting panel 100 is seen from a surface of the substrate 110 on a side opposite to the interconnect substrate 200, the appearance of the first light-emitting-side terminal 150 varies depending on whether or not a portion of the conductive adhesive 306 is connected to the first layer 152 (particularly, in a case where conductive particles of the conductive adhesive 306 come into contact with the first layer 152). Therefore, it is possible to visually check defective connection between the first light-emitting-side terminal 150 and the conductive adhesive 306. In particular, in the present embodiment, the second layer 154 has a comb tooth shape. Accordingly, defective connection between the first light-emitting-side terminal 150 and the conductive adhesive 306 is easily visually checked due to the contrast between the second layer 154 and the conductive adhesive 306.

In addition, since a portion of the conductive adhesive 306 is connected to the first layer 152, it is also possible to suppress an increase in values of connection resistance of the conductive adhesive 306 and the first light-emitting-side terminal 150. In addition, since the first layer 152 is located under the opening of the second layer 154, a portion of the conductive adhesive 306 which is located inside the opening of the second layer 154 is connected to the first layer 152. Therefore, as compared to a case where the first layer 152 is not formed under the opening of the second layer 154, it is possible to reduce values of connection resistance of the conductive adhesive 306 and the first light-emitting-side terminal 150.

Meanwhile, the same effects are obtained with respect to the second light-emitting-side terminal 160 and the connection portion 308 of the conductive adhesive 306.

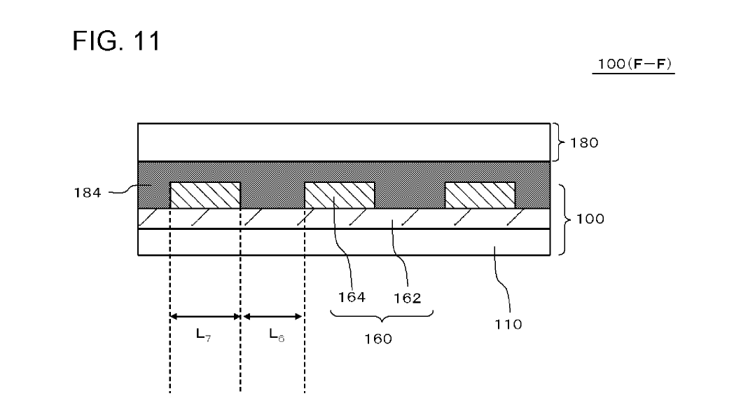

FIG. 11 is a cross-sectional view taken along line F-F in FIG. 3. As described above, a side of the second light-emitting-side terminal 160 which faces the first electrode 120 has a comb tooth shape. A width L₇ of a tooth (in FIG. 11, a portion in which the second layer 164 is present) of the comb tooth shape is larger than a width L₆ of a blank portion (in FIG. 11, a portion in which the second layer 164 is not present) which is a portion between the teeth. It is assumed that a bubble mixed into the adhesive layer 184 has a small diameter. Accordingly, the width L₆ of the blank portion is set to be smaller than the width L₇. For example, in a case where the diameter of the bubble to be observed is assumed to be equal to or less than a half the width L₇, the width L₆ of the blank portion can be set to be equal to or less than a half the width L₇ of the portion which is covered with the second layer 164. On the other hand, in a case where the bubble has a large diameter or in a case where it is difficult for an observer to view a bubble due to a small size of the bubble, the width L₆ of the blank portion may be set to be larger than the width L₇.

Although the second light-emitting-side terminal 160 may be constituted by the first layer 162, it is possible to reduce the resistance of the second light-emitting-side terminal 160 by laminating the second layer 164. Further, it is possible to further reduce the resistance of the second light-emitting-side terminal 160 by increasing the area of the second layer 164 as much as possible.

In addition, as illustrated in the drawing, a plurality of blank portions may be provided in order to confirm that bubbles are mixed over the whole adhesive layer 184. In the example illustrated in the drawing, the plurality of blank portions are aligned in a direction in which the second light-emitting-side terminal 160 extends. In this case, for example, the width L₇ of the portion covered with the second layer 164 is preferably set to be in a range between approximately 125% and approximately 25% of the width L₆ of the blank portion, and is more preferably set to be in a range between equal to or greater than 50% and equal to or less than 100% from the viewpoint of checking the existence of a bubble (from the viewpoint of visibility).

In addition, the conductive members 302 and 304 are separated from the sealing member 180. In other words, a predetermined interval is provided between the sealing member 180 and the conductive members 302 and 304. Thereby, even when the sealing member 180 is formed of a conductive material such as Al, it is possible to prevent the sealing member 180 from short-circuiting the conductive members 302 and 304.

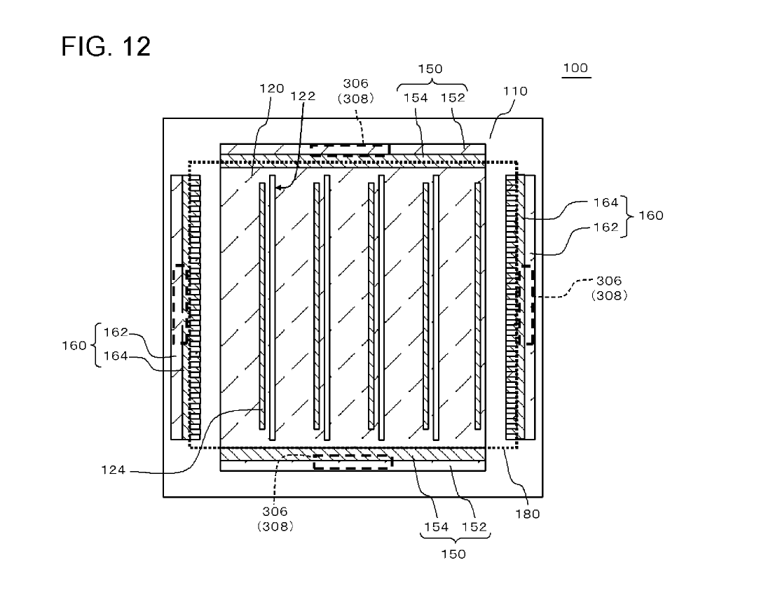

FIG. 12 is a plan view illustrating a first example of a modification example of the light emitting device 10, and corresponds to FIG. 3. As illustrated in the drawing, portions of the second layers 154 and 164 which are connected to the conductive adhesive 306 are not configured as a comb tooth shape. However, since a portion of the conductive adhesive 306 is connected to the second layers 154 and 164 and the other portion of the conductive adhesive 306 is connected to the first layers 152 and 162, the effects described using FIG. 10 are obtained also in a layout illustrated in the drawing.

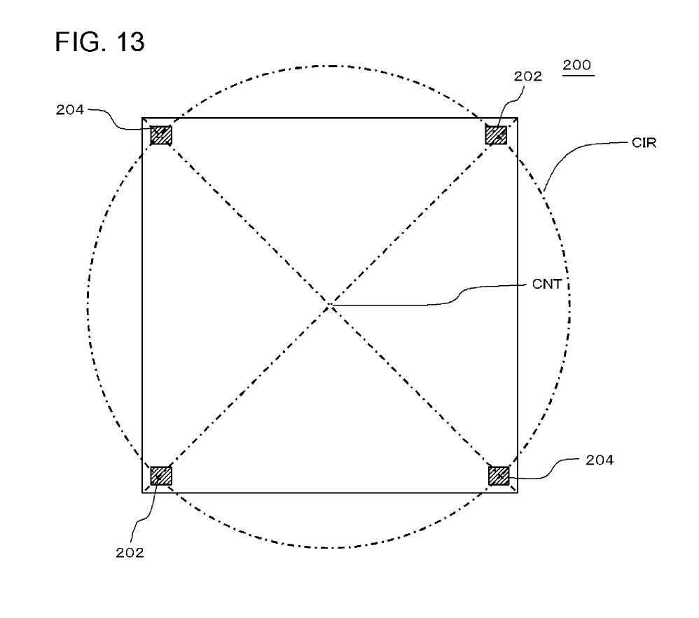

FIG. 13 is a plan view illustrating the arrangement of the first interconnect-side terminal 202 and the second interconnect-side terminal 204. When the conductive member 302 (or the conductive member 304) is connected to the first interconnect-side terminal 202 (or the second interconnect-side terminal 204), it is necessary to use a connecting apparatus. In the present embodiment, the first interconnect-side terminal 202 and the second interconnect-side terminal 204 are located on a circumference of a certain circle CIR. In this manner, it is possible to connect the conductive member 302 to each of the plurality of first interconnect-side terminals 202 and to connect the conductive member 304 to each of the second interconnect-side terminals 204 using the same connecting apparatus only by rotating the interconnect substrate 200. In this case, the manufacturing efficiency of the light emitting device 10 is increased, as compared to a case where a head (for example, a head for solder connection) of the connecting apparatus is moved.

In addition, in the present embodiment, the sum of the number of first interconnect-side terminals 202 and the number of second interconnect-side terminals 204 is an even number. Each of the first interconnect-side terminal 202 and the second interconnect-side terminal 204 is disposed so as to be point-symmetrical to any of the first interconnect-side terminals 202 or the second interconnect-side terminals 204 based on an intersection point CNT between diagonal lines of the substrate 110. Also in this case, it is possible to connect the conductive member 302 to the first interconnect-side terminal 202 (or connect the conductive member 304 to the second interconnect-side terminal 204) by rotating only the interconnect substrate 200.

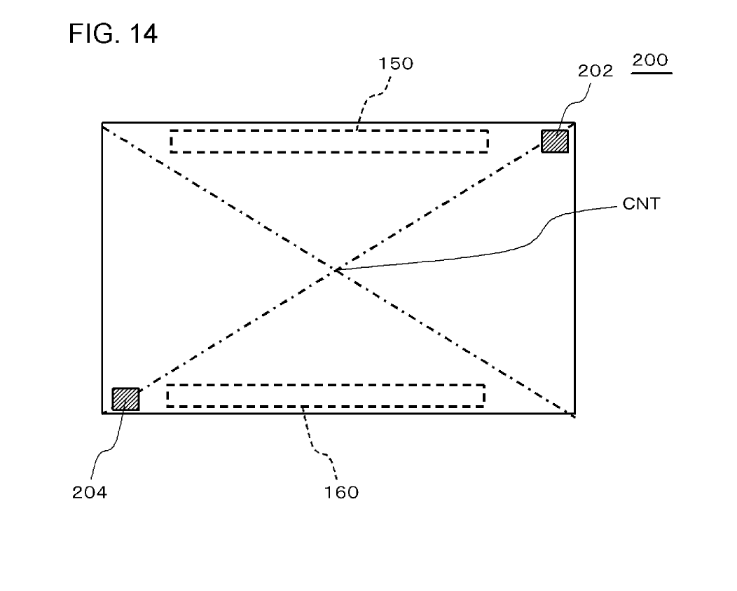

FIG. 14 is a diagram illustrating a second example of the modification example of the light emitting device 10, and corresponds to FIG. 13. In the example illustrated in the drawing, the interconnect substrate 200 has a rectangular shape. The first interconnect-side terminal 202 is formed at an end of one long side of the interconnect substrate 200, and the second interconnect-side terminal 204 is formed at an end of the other long side of the interconnect substrate 200. The first interconnect-side terminal 202 and the second interconnect-side terminal 204 are disposed so as to be point-symmetrical to each other centering on an intersection point CNT between diagonal lines. Also in this case, it is possible to connect the conductive member 302 to the first interconnect-side terminal 202 (or connect the conductive member 304 to the second interconnect-side terminal 204) using the same connecting apparatus only by rotating the interconnect substrate 200.

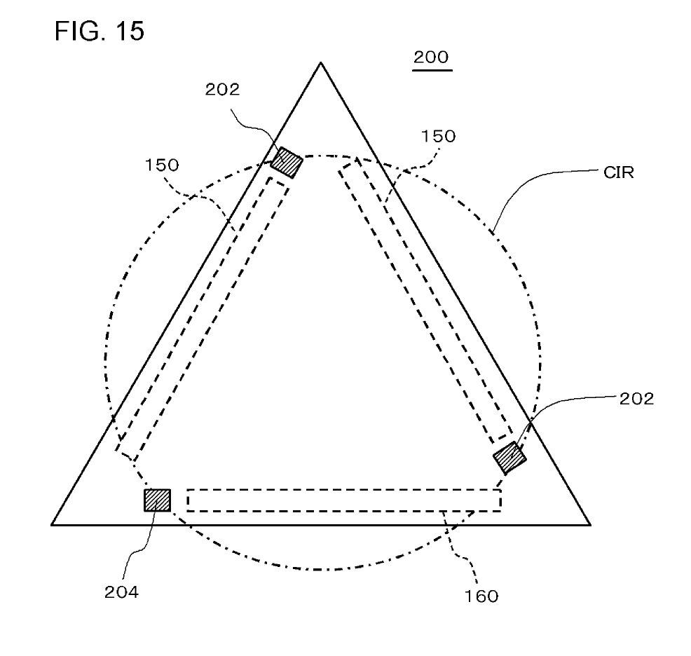

FIG. 15 is a diagram illustrating a third example of the modification example of the light emitting device 10, and corresponds to FIG. 13. In the example illustrated in the drawing, the interconnect substrate 200 is configured as a triangle (for example, an equilateral triangle). The first interconnect-side terminals 202 are formed along two sides of the interconnect substrate 200, and the second interconnect-side terminal 204 is formed along the remaining one side of the substrate 110. Meanwhile, the number of first interconnect-side terminals 202 may be set to be one, and the number of second interconnect-side terminals 204 maybe set to be two instead. The first interconnect-side terminal 202 and the second interconnect-side terminal 204 may be disposed on the same circumference. Also in this case, it is possible to connect the conductive member 302 to the first interconnect-side terminal 202 (or connect the conductive member 304 to the second interconnect-side terminal 204) using the same connecting apparatus only by rotating the interconnect substrate 200.

Meanwhile, it is preferable that connection portions 308 are disposed on the same circumference or disposed so as to be point-symmetrical to each other, similarly to the first interconnect-side terminal 202 and the second interconnect-side terminal 204. In this manner, it is possible to form a plurality of connection portions 308 only by rotating the substrate 110.

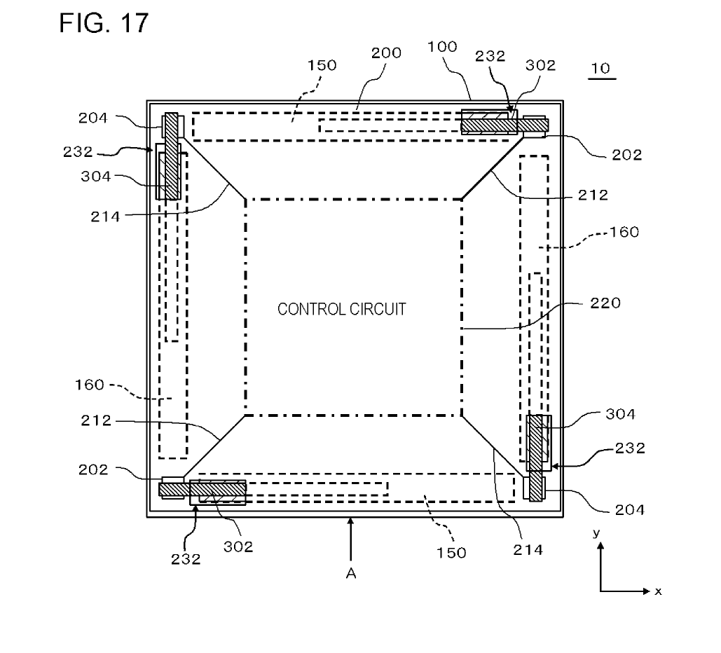

Meanwhile, as illustrated in FIG. 17, an opening 232 may be provided instead of the cutout portion 230. Also in this case, the opening 232 is located at an end of the interconnect substrate 200.

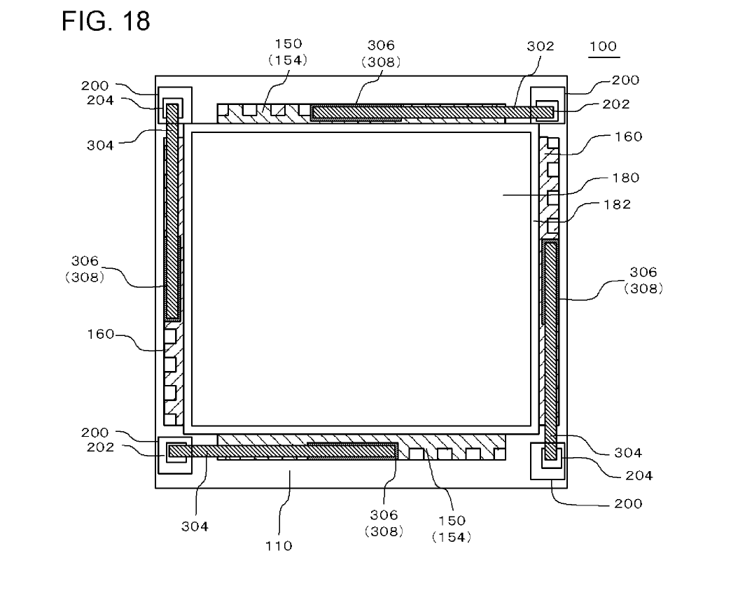

In addition, as illustrated in FIG. 18, the interconnect substrate 200 may be provided separately for each of the first interconnect-side terminal 202 and the second interconnect-side terminal 204. In this case, the interconnect substrate 200 does not need to cover the sealing member 180 and the connection portions 308.

The embodiment and example have been described so far with reference to the accompanying drawings, but are merely illustrative of the invention, and various configurations other than the above can also be adopted.

1. A light emitting device comprising:
a substrate;
a light emitting portion that is formed on the substrate and includes a light emitting element;
a terminal that is formed on the substrate and is connected to the light emitting element;
an interconnect substrate comprising an interconnect-side terminal and a cutout portion; and
a conductive member that connects the terminal and the interconnect-side terminal through the cutout portion,
wherein the terminal extends in a direction of a width of the light emitting portion, and
wherein a length of a connection portion at which the terminal and the conductive member are connected is equal to or greater than 10% of the width of the light emitting portion.

2. The light emitting device according to claim 1, further comprising a sealing member,
wherein the sealing member seals the light emitting portion and comprises a conductive material.

3. The light emitting device according to claim 2,
wherein a length of the connection portion is equal to or less than 80% of the width of the light emitting portion.

4. The light emitting device according to claim 3,
wherein a planar shape of the light emitting portion is a polygonal shape, and
wherein the terminal is along one side of the light emitting portion.

5. The light emitting device according to claim 4,
wherein the conductive member includes a long axis and a short axis,
wherein the light emitting portion is disposed on a side of the conductive member that faces an end of the conductive member extending in a long-axis direction of the conductive member, and
wherein a current or a voltage is applied from the terminal toward the light emitting portion.

6. The light emitting device according to claim 5,
wherein two terminals are disposed so as to be separated from each other with the light emitting portion being located therebetween.

7. The light emitting device according to claim 6,
wherein the terminal includes a first layer which is formed integrally with a first conductive film constituting an electrode of the light emitting portion, and a second layer which is located on the first layer and is formed of a material having resistance lower than that of the first layer.

8. The light emitting device according to claim 7,
wherein a side portion of the second layer facing the light emitting portion is along an end along the long-axis direction of the conductive member.

9. The light emitting device according to claim 8,
wherein the second layer is formed from one end of the light emitting portion to the other end thereof.
